(19) United States
(12) Patent Application Publication
(10) Pub. No.: US 2006/0232452 A1
(43) Pub. Date: Oct. 19, 2006

(54) Method for entropy coding and decoding having improved coding efficiency and apparatus for providing the same

(75) Inventor: Sang-chang Cha, Hwaseong-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/402,967

(22) Filed: Apr. 13, 2006

Related U.S. Application Data
(60) Provisional application No. 60/670,704, filed on Apr. 13, 2005.

(30) Foreign Application Priority Data
Jun. 22, 2005 (KR) 10-2005-0054016

(51) Int. Cl. H03M 7/00

(52) U.S. Cl. 341/50

(57) ABSTRACT

Entropy coding and decoding methods are provided which improve an overall coding efficiency by selectively applying context-based adaptive coding methods having different characteristics. An entropy coding method includes performing context-based adaptive variable length coding on a data symbol; performing context-based adaptive arithmetic coding on the data symbol; receiving information regarding a reference block where the coding efficiency of the context-based adaptive arithmetic coding is higher than that of the context-based adaptive variable length coding; and forming a slice which includes the reference block, and performing the context-based adaptive arithmetic coding on the blocks coded after the reference block.

### CROSS-REFERENCE TO RELATED APPLICATIONS

This application claims priority from Korean Patent Application No. 10-2005-0054016 filed on Jun. 22, 2005 in the Korean Intellectual Property Office, and U.S. Provisional Patent Application No. 60/670,704 filed on Apr. 13, 2005 in the United States Patent and Trademark Office, the disclosures of which are incorporated herein by reference in their entirety.

### BACKGROUND OF THE INVENTION

1. Field of the Invention

Methods and apparatuses consistent with the present invention relate to entropy coding and decoding having improved efficiency, and more particularly, to entropy coding and decoding methods which selectively apply context based adaptive variable length coding and context-based adaptive arithmetic coding having different characteristics to improve the overall coding efficiency and an apparatus for providing the same.

2. Description of the Related Art

Entropy coding converts data into a compressed bit stream for transmission or storage. Entropy coding comprises predictive coding, variable length coding, arithmetic coding, context-based adaptive encoding, and others. Context-based adaptive coding codes data based on information of recently-coded data. Context-based adaptive coding is classified into context-based adaptive variable length coding and context-based adaptive arithmetic coding. Among entropy coding methods, the context-based adaptive arithmetic coding produces the highest compression rate.

Context-based arithmetic coding employs local, spatial and time properties to estimate the probability of an encoded symbol. JSVM (JVT Scalable Video Model) uses the context-based adaptive arithmetic coding method, which adaptively updates the probability model by reflecting the value of the encoded symbol.

However, context-based adaptive arithmetic coding provides better coding efficiency when information accumulates due to an increase of coded blocks. Accordingly, if a context model is initialized to a preset probability model by slice, like in the context-based adaptive arithmetic coding, bits are unnecessarily used until the coding efficiency is uniform after the initialization of the context model.

### SUMMARY OF THE INVENTION

An aspect of present invention provides entropy coding and decoding methods to improve overall coding efficiency by selectively applying context-based adaptive coding methods having different characteristics.

The above stated aspect, as well as other aspects of the present invention, will become clear to those skilled in the art upon review of the following description.

According to an aspect of the present invention, there is provided an entropy coding method, comprising performing context-based adaptive variable length coding with respect to a data symbol, performing context-based adaptive arithmetic coding with respect to the data symbol, receiving information on a reference block where coding efficiency of the context-based adaptive arithmetic coding is higher than that of the context-based adaptive variable length coding, and forming a slice which includes the reference block and performing the context-based adaptive arithmetic coding with respect to blocks coded after the reference block.

According to another aspect of the present invention, there is provided a video coding method, comprising generating a residual by extracting a prediction image from a frame, generating a transform coefficient by spatially transforming the residual, quantizing the transform coefficient, performing context-based adaptive variable length coding on the data symbol of the quantized transform coefficient, performing context-based adaptive arithmetic coding on the data symbol of the quantized transform coefficient, receiving information on a reference block where coding efficiency of the context-based adaptive arithmetic coding is higher than that of the context-based adaptive variable length coding, forming a slice which includes the reference block and performing the context-based adaptive arithmetic coding on blocks coded after the reference block, generating a bit stream that comprises information regarding the reference block, and transmitting the bit stream.

According to another aspect of the present invention, there is provided an entropy decoding method, comprising interpreting a bit stream and extracting information on a reference block where context-based adaptive arithmetic coding begins, performing context-based adaptive variable length decoding on a bit stream of a block to be restored if the block to be restored is decoded earlier than the reference block, and performing context-based adaptive arithmetic decoding on the bit stream of the block to be restored.

According to another aspect of the present invention, there is provided a video decoding method, comprising interpreting a bit stream and extracting information on a reference block where context-based adaptive arithmetic coding begins, performing context-based adaptive variable length decoding on a bit stream of a block to be restored if the block to be restored is decoded earlier than the reference block, performing context-based adaptive arithmetic decoding on the bit stream of the block to be restored, inverse-quantizing the decoded value, inverse-spatially transforming the inverse-quantized value and restoring a residual signal, and adding a restored prediction image to the residual signal and restoring a video frame.

According to another aspect of the present invention, there is provided a video encoder, comprising means to generate a residual by extracting a prediction image from a frame, means to generate a transform coefficient by spatial transforming the residual, means to quantize the transform coefficient, means to perform context-based adaptive variable length coding on a data symbol of the quantized transform coefficient, means to perform context-based adaptive arithmetic coding on a data symbol of the quantized transform coefficient, means to receive information on a reference block where coding efficiency of the context-based adaptive arithmetic coding is higher than that of the context-based adaptive variable length coding, means to form a slice which includes the reference block, and to perform the context-based adaptive arithmetic coding on blocks coded after the reference block, means to generate a bit stream that comprises information regarding the reference block; and means to transmit the bit stream.

According to another aspect of the present invention, there is provided a video decoder, comprising means to interpret a bit stream and to extract information on a reference block where context-based adaptive arithmetic coding begins, means to perform context-based adaptive variable length decoding on a bit stream of a block to be restored if the block to be restored is decoded earlier than the reference block, means to perform context-based adaptive arithmetic decoding on the bit stream of the block to be restored, means to inverse-quantize the decoded value, means to inverse-spatially transform the inverse-quantized value and to restore a residual signal, and means to add a restored prediction image to the residual signal and to restore a video frame.

### BRIEF DESCRIPTION OF THE DRAWINGS

The above and other aspects of the present invention will become more apparent by describing in detail exemplary embodiments thereof with reference to the attached drawings in which:

FIG. 1 is a graph to compare coding efficiency of context-based adaptive variable length coding and context-based adaptive arithmetic coding;

FIG. 2 illustrates the concept of an entropy coding method according to an exemplary embodiment of the present invention;

FIG. 3 is a block diagram of a configuration of a video encoder according to an exemplary embodiment of the present invention;

FIG. 4 is a block diagram of a configuration of a video decoder according to an exemplary embodiment of the present invention;

FIG. 5 is a flowchart of a video coding method according to an exemplary embodiment of the present invention; and

FIG. 6 is a flowchart of a video decoding method according to an exemplary embodiment of the present invention.

### DETAILED DESCRIPTION OF THE EXEMPLARY EMBODIMENTS

Aspects of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these exemplary embodiments are provided so that this disclosure will be thorough and complete and will fully convey the concept of the invention to those skilled in the art, and the present invention will only be defined by the appended claims. Like reference numerals refer to like elements throughout the specification.

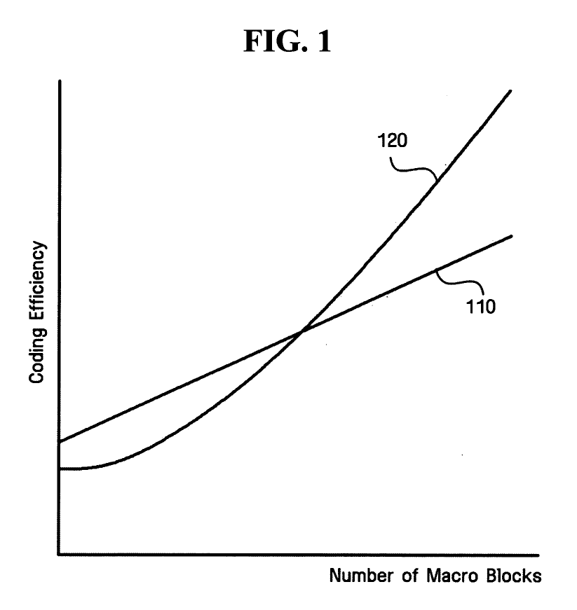

FIG. 1 is a graph comparing the coding efficiency of context-based adaptive variable length coding and context-based adaptive arithmetic coding.

Context-based adaptive variable length coding (hereinafter, to be referred to as CAVLC) is variable length coding that employs information on neighboring blocks that have been coded recently. Variable length coding is performed according to one table selected from a plurality of coding reference tables according to the information of the neighboring blocks of a currently-coded block. This method is employed to encode residuals, i.e., transform coefficient blocks in zigzags. CAVLC is designed to use characteristics of quantized blocks.

The blocks that are predicted, converted and quantized are almost zero. CAVLC uses run-level coding to produce a series of zeros. Transform coefficients that are not 0 and that have the highest value after a zigzag scanning have a value of ±1, and CAVLC signalizes the number of ±1 transform coefficients with high frequency using a compression method. Without the value of 0, the values of transform coefficients of neighboring blocks are related to each other. The value of the transform coefficient is encoded by a look-up table. The selection of the look-up table depends on the number of the transform coefficients that are not zero. The level of the non-zero transform coefficients is larger at the beginning of a realigned array and becomes smaller at high frequency. CAVLC adaptively selects the VLC look-up table for a level parameter according to the size of the recently-coded level.

CAVLC encoding of the transform coefficients of a single block is performed as follows.

The non-zero transform coefficients and ±1 transform coefficients at high frequency within a block are encoded, and the signs of the ±1 transform coefficients are encoded. Then, the levels of the remaining non-zero transform coefficients are encoded. The zero before the last transform coefficient is encoded and the run of each zero is encoded.

Context-based adaptive arithmetic coding selects a probability model for each symbol according to the context of a data symbol, adapts the probability estimates based on local statistics, and employs arithmetic coding to achieve excellent compression performance. The process of coding the data symbol is as follows.

1. Binarization: Binary arithmetic coding (Binarization) of the context-based adaptive arithmetic coding method converts not a binary value, but a symbol value into a binary number. Context-based adaptive binary arithmetic coding (hereinafter, to be referred to as CABAC) encodes only a binary decision. Not a binary value, but the symbol, e.g., a transform coefficient or a symbol having 2 or more values, such as a motion vector, is converted into a binary code before the arithmetic coding is performed. The process is similar to converting the data symbol into a variable length code. However, the binary code is further encoded by an arithmetic coder before being transmitted.

Hereinafter, CABAC will be described as an example of context-based adaptive arithmetic coding, however, the present invention is not limited thereto.

The processes of selecting a context model, arithmetic encoding, and updating the probability model are repeated with respect to each bit of binarized symbols, i.e., a bin.

2. Selecting context model: The context model is a probability model of one or more bins of binarized symbols. The context model is selected from applicable models based on statistics of the recently-coded data symbols. The context model stores the probability that each bin is a 1 or 0.

3. Arithmetic encoding: An arithmetic coder encodes each bin according to the selected probability model. Each bin has two subprobability ranges corresponding to 0 and 1.

4. Updating probability: The selected context model is updated based on the actual-coded value. That is, if the value of the bin is 1, the frequency of 1 increases by 1.

CABAC selects the context model by slice, and the probability value of the context model is initialized as a certain constant table by slice. The CABAC reflects the statistics of the recently-coded data symbol and continuously upgrades the context model. Thus, a certain amount of information should accumulate to provide better coding efficiency than the conventional VLC. Accordingly, if the context model is initialized to a predefined probability model by slice, bits are unnecessarily used to compensate lowered performance due to the increase of blocks after the initialization of the context model.

FIG. 1 is a graph showing the relationship between the coding efficiency of CAVLC and CABAC and the number of macroblocks. Both CAVLC and CABAC are included in the context-based adaptive entropy coding method which employs the information of the current-coded blocks to code next blocks, thereby improving the coding efficiency in direct proportion to the number of coded blocks. However, as CAVLC uses the predefined code table to perform the entropy coding, coding efficiency increases almost in proportion to the number of macroblocks (110). In CABAC, coding efficiency is low at the beginning as the probability value of the context model is initialized to a certain constant table by slice, and it drastically increases as the number of macroblocks increases (120). Generally, the lowered coding efficiency due to the initialization of the context model when CABAC is used is complemented by CAVLC, which provides better coding efficiency at the beginning of the slice than CABAC. Thus, the overall coding performance is improved.

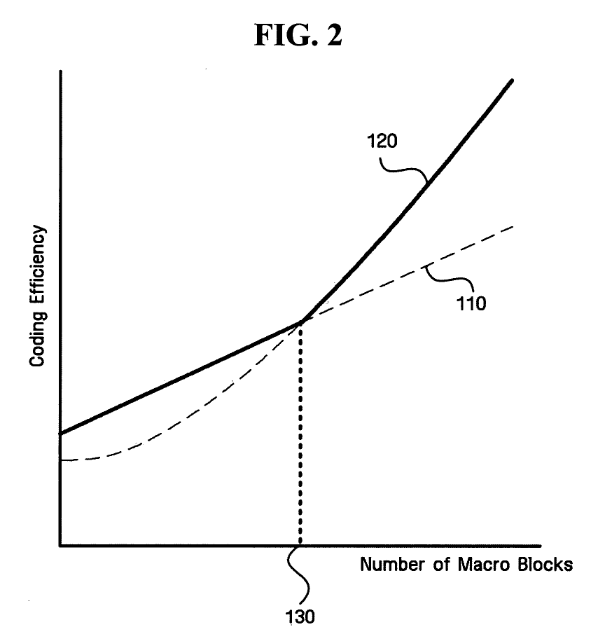

FIG. 2 illustrates the concept of the entropy coding method according to an exemplary embodiment of the present invention.

In the entropy coding method according to an exemplary embodiment of the present invention, a macroblock (a sub block) 130 in which the coding efficiency of CABAC is higher than that of CAVLC will be referred to as a reference block. Here, CABAC is employed, and CAVLC is implemented for a previously-coded macroblock. To perform CABAC on the macroblock 130, CAVLC is performed on previous blocks of the macroblock 130, and the context model of CABAC is updated. That is, the blocks previous to the macroblock 130 transmit CAVLC-coded values, and perform CABAC, thereby reflecting statistics of the previous blocks in the macro block 130, where coding efficiency is reversed, using the updated context model.

In a first exemplary embodiment of the present invention, CABAC alone is performed from the time 130 when the CABAC coding efficiency exceeds the CAVLC coding efficiency. Thus, an encoder transmits to a decoder information on the macroblock where CABAC begins, e.g., information on which block of the slice the reference block where the CABAC begins is included.

Meanwhile, in another exemplary embodiment of the present invention, the entropy coding may be performed by selecting one of CABAC and CAVLC; that is, entropy coding can be performed by selecting the method that provides better coding efficiency by macroblocks or sub-blocks. At this time, a slice head or a head of each block may be inserted with a bit which comprises information on which entropy coding method is used for each block.

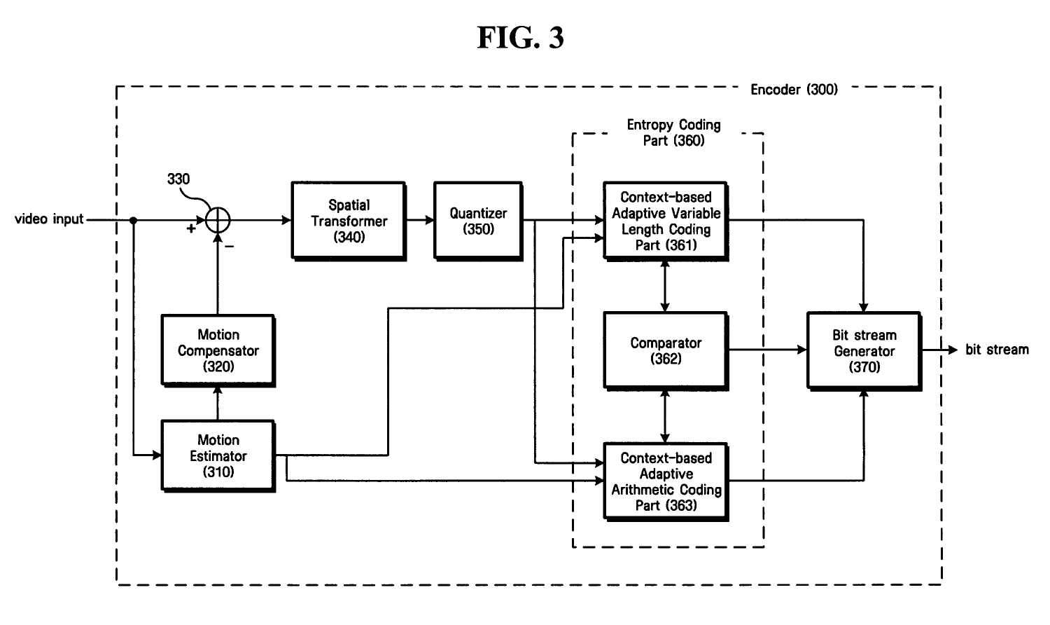

FIG. 3 is a block diagram of a configuration of a video encoder according to an exemplary embodiment of the present invention.

The video encoder 300 may comprise a spatial transformer 340, a quantizer 350, an entropy encoder (entropy coding part) 360, a motion estimator 310, a motion compensator 320, a bit stream generator 370.

The motion estimator 310 performs motion estimation on a current frame and calculates a motion vector based on a reference frame of input video frames. A block matching algorithm is used in the motion estimation. That is, as the motion block is moved within a certain search area of the reference frame by pixel, a displacement is estimated as the motion vector in the case where the error is the lowest. A fixed-sized motion block, or a motion block having a variable size created by hierarchical variable size block matching (HVSBM) may be used for the motion estimation. The motion estimator 310 supplies motion data including the motion vector, the motion block size, the reference frame number achieved by the motion estimate, to the entropy encoder(entropy coding part) 360.

The motion compensator 320 uses the motion vector calculated by the motion estimator 310 to perform motion compensation with respect to the reference frame, and to generate a prediction frame for the current frame.

A divider 330 divides the prediction frame generated from the current frame by the motion compensator 320 to remove the redundancy of the video.

The spatial transformer 340 removes the spatial redundancy from the frame from which the divider 330 has removed redundancy using a spatial transform method supporting spatial scalability. The spatial transform method may be the discrete cosine transform (DCT), wavelet transform, or others. Coefficients generated by the spatial transform are referred to as transform coefficients.

The quantizer 350 quantizes the transform coefficient generated by the spatial transformer 340. Quantization means that the transform coefficient described as a certain real-numbered value is divided into periods to be described as a discrete value and to be matched by a predetermined index.

The entropy coding part 360 non-losslessly signalizes the transform coefficient quantized by the quantizer 350, and the data symbols comprising the motion data provided by the motion estimator 310. The entropy coder 360 may comprise a context-based adaptive variable length coding part 361, a context-based adaptive arithmetic coding part 363, and a comparator 362.

The context-based adaptive variable length coding part 361 performs the context-based adaptive variable length coding on the quantized transform coefficient and the data symbols comprising the motion information, and supplies the number of bits of the coded bit stream to the comparator 362. The context-based adaptive arithmetic coding part 363 performs the context-based adaptive arithmetic coding on the quantized transform coefficient and the data symbols comprising the motion information, and supplies the number of bits of the coded bit stream to the comparator 362.

The comparator 362 compares the number of accumulated bits used to perform the context-based adaptive variable length coding on the first block to the current block of the slice, and the number of accumulated bits used to perform the context-based adaptive arithmetic coding on the first block to the current block of the slice to supply information on the coding method that uses less bits to the bit stream generator 370.

The bit stream generator 370 collects the information on the coding method that uses less bits from the comparator 362, and the coded value received from the context-based adaptive variable length coding part 361, and the coded value received from the context-based adaptive arithmetic coding part 363 in order to generate a bit stream to be transmitted to the decoder. The coding part can be a coder.

In an exemplary embodiment of the present invention, according to the information on the coding method that uses less bits provided from the comparator 362, the bit stream generator 370 may insert the information on the reference block in which coding efficiency of the CABAC is higher than that of the CAVLC coding, to a unit in which the context model of CABAC is initialized. If the context model of the CABAC is initialized by slice, information on which block of the slice was used may be inserted into the slice header.

Meanwhile, in another exemplary embodiment of the present invention, the bit stream generator 370 may insert, by bit, information on which entropy coding method is used for each block according to the information from the comparator 362 on the coding method that uses less bits. The information may be inserted into the slice header or the header of each block.

If the video encoder 300 supports closed-loop video encoding to reduce drift errors between an encoder terminal and a decoder terminal, it may further comprise a inverse quantizer, a inverse spatial transformer, and others.

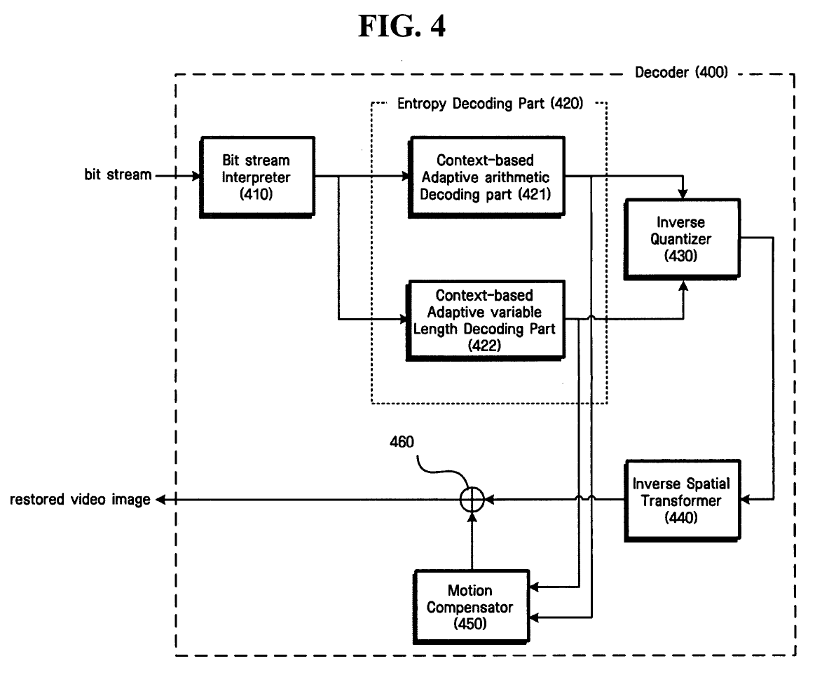

FIG. 4 is a configuration of the video decoder according to an exemplary embodiment of the present invention.

The video decoder 400 may comprise a bit stream interpreter 410, an entropy decoding part 420, a inverse quantizer 430, a inverse spatial transformer 440, and a motion compensator 450. The decoding part can be a decoder.

The bit stream interpreter 410 interprets the bit stream transmitted by the encoder to extract information on which block of the slice or frame the CABAC used to compress the bit stream, or information on which entropy coding method was used to compress each block, and supplies the information to the entropy decoding part 420.

The entropy decoding part 420 performs a non-lossless decoding using an inverse entropy coding method to extract motion data, texture data, and others. The texture information is supplied to the inverse quantizer 430, and the motion data is supplied to the motion compensator 450. The entropy decoder 420 may comprise a context-based adaptive arithmetic decoder part 421 and a context-based adaptive variable length decoder part 422.

The context-based adaptive arithmetic decoder 421 and the context-based adaptive variable length decoder 422 decode the bit stream corresponding to a block according to the information supplied by the bit stream interpreter 410. If the bit stream interpreter 410 supplies information on which block of the slice or the frame the CABAC used to compress the bit stream, the context-based adaptive variable length decoder 422 entropy decodes the bit stream with respect to the blocks before the CABAC began. Meanwhile, the context-based adaptive arithmetic decoding part 421 entropy-decodes the bit stream with respect to the blocks after the CABAC began. Here, the blocks before the CABAC began are decoded using context-based adaptive variable length decoding, and the context-based adaptive arithmetic decoding is performed, thereby updating the context model for performing the context based adaptive arithmetic decoding on the blocks after the CABAC began.

Meanwhile, if the bit stream interpreter 410 supplies information on which entropy decoding method is used to compress the respective blocks, the entropy decoding is performed to the respective blocks, corresponding to the entropy encoding applied by the encoder.

The inverse quantizer 430 inversely-quantizes the texture information received from the entropy decoder 420. The inverse quantization means that a value transmitted from the encoder terminal 300 with a predetermined index is used to find a matching quantized coefficient.

The inverse spatial transformer 440 performs an inverse spatial transform, and restores the coefficients generated by the inverse quantization into a residual image in normal space. The motion compensator 450 uses the motion data supplied from the entropy decoder 420 and motion-compensates the pre-restored video frame to generate a motion compensation frame. The motion compensation is applied only to the current frame which has been coded through the prediction process using the motion compensation in the encoder terminal.

An adder 460 adds the residual image restored by the inverse spatial transformer 440 to the motion-compensated image supplied by the motion compensator 450 to restore the video frame.

The elements in FIGS. 3 and 4 can be, but are not limited to, a software or hardware component, such as a Field Programmable Gate Array (FPGA) or an Application Specific Integrated Circuit (ASIC). The elements may advantageously be configured to reside on the addressable storage medium and configured to execute on one or more processors. The functionality provided for in the elements may be realized by separated elements, or realized to perform certain functions through a plurality of elements. Further, the elements may be realized to execute one or more computers in a system.

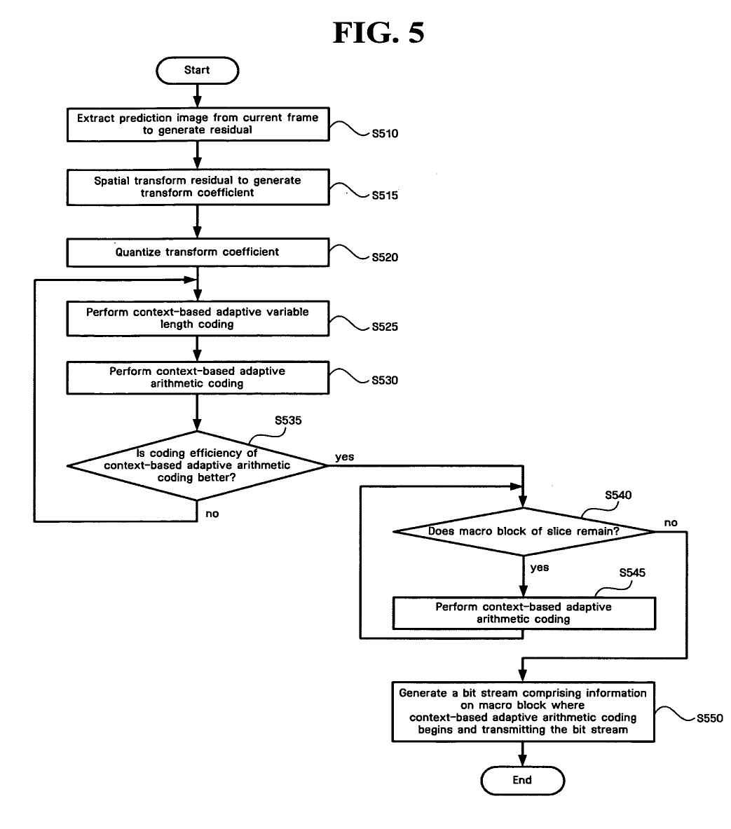

FIG. 5 is a flowchart of the video coding method according to an exemplary embodiment of the present invention.

The video encoder 300 according to an exemplary embodiment of the present invention divides the prediction image from the current frame to be compressed in order to generate a residual (S510). Then, the video encoder 300 generates the transform coefficient by spatially transforming the residual (S515), and quantizes the transform coefficient (S520). Also, the video encoder 300 performs the entropy coding on the data symbols of the quantized transform coefficients (S525 or S545), and generates the bit stream in order to transmit it to the decoder (S550).

The process of performing the entropy coding is as follows.

The context-based adaptive variable length coding part 361 performs the CAVLC on the data symbols of one block in the video frame (S525), and the context-based adaptive arithmetic coding part 363 performs CABAC on the data symbols (S530). The comparator 362 compares the coding efficiency of CAVLC and CABAC (S535). If the coding efficiency of CAVLC is better (“No” in operation S535), CAVLC and CABAC are performed on the next block (S525 and S530).

If coding efficiency of CABAC is better than that of CAVLC (“Yes” in operation S535), CABAC is performed with respect to blocks after the blocks in which the slice or the CABAC context model of was initialized (S540 and S545). If the entropy coding is completed with respect to all the macroblocks of the slice, the bit stream generator 370 inserts into the slice header the information on the reference block from which the CABAC was applied, and generates the bit stream comprising the CAVLC coded value of the blocks before the reference block and, the CABAC coded value of the blocks after the reference block in order to transmit it to the decoder.

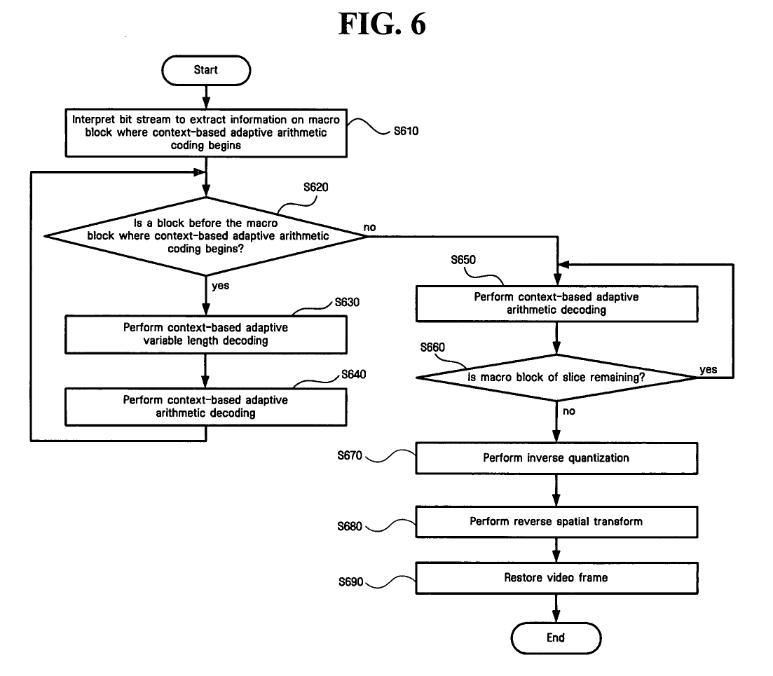

FIG. 6 is a flowchart of the video decoding method according to an exemplary embodiment of the present invention.

The bit stream interpreter 410 of the video decoder 400 according to an exemplary embodiment of the present invention interprets the bit stream received from the encoder to extract the information of the block where CABAC begins (S610). The entropy coding is performed according to the information of the block where CABAC begins (S620 or S660). The entropy-coded value is inversely-quantized (S670), and is inverse-spatially transformed to restore the residual signal (S680). The prediction image restored by the motion compensation is added to the restored residual signal to restore the video frame (S690).

The entropy decoding process is performed as follows.

If the current block is before the block where CABAC begins (“Yes” in operation S620), the context-based adaptive variable length decoding is performed on the bit stream of the current block to be restored (S630), and the context-based adaptive arithmetic decoding is performed on the bit stream (S640).

Meanwhile, if the block to be restored is the block where CABAC begins (“No” in operation S620), the context-based adaptive arithmetic decoding is performed on the block (S650), and the context-based arithmetic decoding is performed on the remaining blocks of the slice to losslessly decode them (S650 and S660).

The entropy-decoded value is inversely-quantized (S670), and is inverse-spatially transformed (S680). Then, the entropy-coded value is restored as the residual signal and the prediction image. Then, the adder 460 adds the residual signal to the prediction image to restore the video frame (S690).

The process of entropy coding and decoding according to an exemplary embodiment of the present invention is described using a macroblock, but it is not limited thereto. Alternatively, the processes of entropy coding and decoding according to the embodiment of the present invention may be performed by using a sub-block. Thus, the block according to the present invention comprises the macroblock and the sub-block.

As described above, according to the entropy coding and decoding methods of the present invention, the overall video coding efficiency is enhanced by selectively applying the context-based adaptive coding methods having different characteristics.

It will be understood by those of ordinary skill in the art that various changes in the form and details may be made therein without departing from the spirit and scope of the present invention as defined by the following claims. Therefore, the scope of the invention is given by the appended claims, rather than by the preceding description, and all variations and equivalents which fall within the range of the claims are intended to be embraced therein.

What is claimed is:

1. An entropy coding method comprising:
performing context-based adaptive variable length coding with respect to a data symbol;
performing context-based adaptive arithmetic coding with respect to the data symbol;
receiving information regarding a reference block where a coding efficiency of the context-based adaptive arithmetic coding is higher than that of the context-based adaptive variable length coding; and
forming a slice which includes the reference block and performing the context-based adaptive arithmetic coding with respect to blocks coded after the reference block.

2. The entropy coding method of claim 1, wherein the coding efficiency decreases as the number of accumulated bits used to code the data symbol increases.

3. The entropy coding method of claim 1, wherein the information regarding the reference block comprises information relating to which block of the slice includes the reference block.

4. A video coding method comprising:
generating a residual by extracting a prediction image from a frame;
generating a transform coefficient by spatially transforming the residual;
quantizing the transform coefficient;
performing context-based adaptive variable length coding on the data symbol of the quantized transform coefficient;
performing context-based adaptive arithmetic coding on the data symbol of the quantized transform coefficient;
receiving information regarding a reference block where a coding efficiency of the context-based adaptive arithmetic coding is higher than that of the context-based adaptive variable length coding;
forming a slice which includes the reference block and performing the context-based adaptive arithmetic coding on blocks coded after the reference block;
generating a bit stream that comprises information regarding the reference block; and
transmitting the bit stream.

5. The video coding method of claim 4, wherein the coding efficiency decreases as the number of accumulated bits that are used to code the data symbol increases.

6. The video coding method of claim 4, wherein the information regarding the reference block comprises information relating to which block of the slice includes the reference block.

7. An entropy decoding method comprising:
interpreting a bit stream comprising coded values of a plurality of blocks in a slice and extracting information regarding a reference block where context-based adaptive arithmetic coding begins;
performing context-based adaptive variable length decoding on a bit stream of a block to be restored if the block to be restored is decoded earlier than the reference block; and
performing context-based adaptive arithmetic decoding on the bit stream of the block to be restored.

8. The entropy decoding method of claim 7, wherein the information regarding the reference block comprises information relating to which block of the slice includes the reference block.

9. A video decoding method comprising:
interpreting a bit stream comprising coded values of a plurality of blocks in a slice and extracting information regarding a reference block where context-based adaptive arithmetic coding begins;
performing context-based adaptive variable length decoding on a bit stream of a block to be restored if the block to be restored is decoded earlier than the reference block;
performing context-based adaptive arithmetic decoding on the bit stream of the block to be restored;
inverse-quantizing the decoded value;
inverse-spatially transforming the inverse-quantized value and restoring a residual signal; and
adding a restored prediction image to the residual signal and restoring a video frame.

10. The video decoding method of claim 9, wherein the information regarding the reference block comprises information relating to which block of the slice includes the reference block.

11. A video encoder comprising:
means for generating a residual by extracting a prediction image from a frame;
means for generating a transform coefficient by spatial transforming the residual;
means for quantizing the transform coefficient;
means for performing context-based adaptive variable length coding on a data symbol of the quantized transform coefficient;
means for performing context-based adaptive arithmetic coding on a data symbol of the quantized transform coefficient;
means for receiving information regarding a reference block where a coding efficiency of the context-based adaptive arithmetic coding is higher than that of the context-based adaptive variable length coding;
means for forming a slice which includes the reference block, and for performing the context-based adaptive arithmetic coding on blocks coded after the reference block;
means for generating a bit stream that comprises information regarding the reference block; and
means for transmitting the bit stream.

12. The video encoder of claim 11, wherein the coding efficiency decreases as the number of accumulated bits that are used to code the data symbol increases.

13. The video encoder of claim 11, wherein the information regarding the reference block comprises information relating to which block of the slice includes the reference block.

14. A video decoder comprising:
means for interpreting a bit stream comprising coded values of a plurality of blocks in a slice and for extracting information regarding a reference block where context-based adaptive arithmetic coding begins;
means for performing context-based adaptive variable length decoding on a bit stream of a block to be restored if the block to be restored is decoded earlier than the reference block;
means for performing context-based adaptive arithmetic decoding on the bit stream of the block to be restored;
means for inverse-quantizing the decoded value;
means for inverse-spatially transforming the inverse-quantized value and for restoring a residual signal; and
means for adding a restored prediction image to the residual signal and for restoring a video frame.

15. The video decoder of claim 14, wherein the information regarding the reference block comprises information relating to which block of the slice includes the reference block.

16. A video encoder comprising:
a divider which generates a residual by extracting a prediction image from a frame;
a spatial transformer which generates a transform coefficient by spatial transforming the residual;
a quantizer which quantizes the transform coefficient;
a context-based adaptive variable length coding unit which performs context-based adaptive variable length coding on a data symbol of the quantized transform coefficient;
a context-based adaptive arithmetic coding unit which performs context-based adaptive arithmetic coding on a data symbol of the quantized transform coefficient;
a comparator which determines a reference block where a coding efficiency of the context-based adaptive arithmetic coding is higher than that of the context-based adaptive variable length coding, and a bit stream generator which collects information regarding the reference block from the comparator, inserts the information regarding the reference block into the header of a slice, generates a bit stream that comprises the information regarding the reference block, and transmits the stream.

17. The video encoder of claim 16, wherein the coding efficiency decreases as the number of accumulated bits that are used to code the data symbol increases.

18. The video encoder of claim 16, wherein the information regarding the reference block comprises information relating to which block of the slice includes the reference block.

19. A video decoder comprising:
a bit stream interpreter which interprets a bit stream comprising the coded values of a plurality of blocks in a slice and extracts information regarding a reference block;
a context-based adaptive variable length decoding part which performs context-based adaptive variable length decoding on a bit stream of a block to be restored if the block to be restored is decoded earlier than the reference block;
a context-based adaptive arithmetic decoding part which performs context-based adaptive arithmetic decoding on the bit stream of the block to be restored;
an inverse quantizer which inverse-quantizes the decoded value;
an inverse spatial transformer which inverse-spatially transforms the inverse-quantized value and restores a residual signal; and
an adder which adds a restored prediction image to the residual signal and restores a video frame.

20. The video decoder of claim 19, wherein the information regarding the reference block comprises information relating to which block of the slice includes the reference block.

21. A computer-readable recording medium which records a computer-readable program that performs the method of claim 1.

22. A computer-readable recording medium which records a computer-readable program that performs the method of claim 4.

23. A computer-readable recording medium which records a computer-readable program that performs the method of claim 7.

24. A computer-readable recording medium which records a computer-readable program that performs the method of claim 9.

25. A computer-readable recording medium which records a computer-readable program that performs the method of claim 11.

26. A computer-readable recording medium which records a computer-readable program that performs the method of claim 14.
